(19) United States
(12) Patent Application Publication
(10) Pub. No.: US 2010/0209625 A1
(43) Pub. Date: Aug. 19, 2010

(54) VOLTAGE VARIABLE TYPE THINFILM DEPOSITION METHOD AND APPARATUS THEREOF

(76) Inventor: Sang-Youl Bae, Gyeonggi-do (KR)

Correspondence Address: IPLA P.A., 3550 WILSHIRE BLVD., 17TH FLOOR, LOS ANGELES, CA, 90010, US

(21) Appl. No.: 12/681,941

(22) PCT Filed: Oct. 10, 2007
(86) PCT No.: PCT/KR07/04920

§ 371 Date: Apr. 7, 2010

(51) Int. Cl. C23C 16/00; B05C 11/00

(52) U.S. Cl. 427/585; 118/696

(57) ABSTRACT

A voltage variable-type thin film deposition device and method is disclosed. The voltage variable-type thin film deposition method includes applying bias voltage while continuously varying the magnitude of the bias voltage for a period of time set by a user, —determining whether to use preset bias voltage values; depositing a thin film based on the preset bias voltage values if, as a result of the determination, it is determined to use the preset bias voltage values, and setting new bias voltage values if it is determined to use new bias voltage values; selecting whether to apply voltage from low bias voltage or from high bias voltage when new bias voltage values are set; selecting an increasing/decreasing slop type for the bias voltage when the starting voltage is selected; and starting to deposit the thin film when the voltage slope is selected.

### TECHNICAL FIELD

The present invention relates, in general, to a voltage variable-type thin film deposition method and device used to fabricate semiconductors or to coat the surfaces of various types of moldings, and, more particularly, to a voltage variable-type thin film deposition method and device, in which bias voltage is continuously varied, and a thin film is deposited at selected starting bias voltage based on the intended use of the thin film, thereby improving thin film characteristics and deposition characteristics, and simplifying equipment.

### BACKGROUND ART

Generally, in order to fabricate semiconductors or deposit (or coat) thin films on various types of moldings, thin film deposition devices, which can deposit thin films each having a thickness ranging from several to several tens of micrometers, have been used. Such a thin film deposition device has been required to fabricate a thin film which can realize various requirements, such as electrical conductivity, toughness, heat resistance, and abrasion resistance, based on the intended use and circumstances thereof.

Therefore, there have been efforts to improve a thin film deposition method and various deposition circumstances, such as a thin film material and injected reaction gas, thereby providing a thin film having excellent characteristics, realizing the above-described electrical conductivity, toughness, heat resistance, and abrasion resistance.

For example, as shown in FIG. 1, when a molding is coated with a thin film, in order to improve both abrasion resistance and impact resistance which are properties that negatively correspond to each other, Titanium Nitride (TiN) thin film layers Layer 1 and Layer 3, having excellent lubricity, or other various thin film layers (not shown) are layered on Aluminum Nitride (AlN) thin film layers Layer 2 and Layer 4, having both excellent abrasion resistance and heat resistance, so that the coating of a multi-layered thin film 10 which can realize both abrasion resistance and impact resistance can be achieved.

As described above, when the aluminum nitride thin film layers Layer 2 and Layer 4 and the titanium nitride thin film layers Layer 1 and Layer 3 are deposited to form a multi-layer structure Layer 1 to Layer 4, any characteristic of the above-described abrasion resistance or impact resistance can be improved in the respective layers Layer 1, Layer 2, Layer 3, and Layer 4. However, there are problems in that joining layers (or separation layers) are formed between the respective layers Layer 1, Layer 2, Layer 3, and Layer 4, so that cracks and separation occur therebetween, and it is not possible to significantly improve the characteristics of the thin film 10 for an entire multilayer structure.

### DISCLOSURE

### Technical Problem

Accordingly, the present invention has been made keeping in mind the above problems occurring in the prior art, and an object of the present invention is to provide a voltage variable-type thin film deposition method and device, in which bias voltage is continuously varied, and a thin film is deposited at selected starting bias voltage based on the intended use of the thin film, thereby improving thin film characteristics and deposition characteristics and simplifying equipment, when semiconductors are fabricated or thin films are coated on the surfaces of various types of moldings.

### Technical Solution

In order to accomplish the above object, the present invention provides a voltage variable-type thin film deposition method, including applying bias voltage, leading thin film material to a targeted object such that the thin film material is deposited on the targeted object, while continuously varying a magnitude of the bias voltage for a period of time set by a user.

Here, the magnitude of the bias voltage increases or decreases at least once for the period of time set by the user.

Further, the magnitude of the bias voltage increases and then decrease or decreases and then increases at least once for the period of time set by the user.

Further, the bias voltage is applied to any one of a Physical Vapor Deposition (PVD)-type thin film deposition device, a Chemical Vapor Deposition (CVD)-type thin film deposition device, and a PVD/CVD mixture-type thin film deposition device.

Further, the bias voltage is any one of Direct Current (DC) bias voltage and pulse-type bias voltage, and the thin film material led and deposited by the bias voltage is one or more types of material.

Here, variation in the bias voltage ranges from 0.5 V or higher to 10 V or lower per minute.

Further, the bias voltage is varied such that difference between a maximum value and a minimum value of bias voltage is 50 V or higher.

Further, a maximum value of the bias voltage ranges from 100 V or higher to 250 V or lower.

Further, a minimum value of the bias voltage ranges from 30 V or higher to 80 V or lower.

Further, the bias voltage is varied by applying voltage from low voltage to high voltage or from high voltage to low voltage.

Furthermore, the above-described voltage variable-type thin film deposition method including a determination step of determining whether to use preset bias voltage values; a step of depositing a thin film based on the preset bias voltage values if, as a result of the determination, it is determined to use the preset bias voltage values, and setting new bias voltage values if it is determined to use new bias voltage values; a starting voltage selection step of selecting whether to apply voltage from low bias voltage or from high bias voltage when new bias voltage values are set; a voltage slope selection step of selecting an increasing/decreasing slop type for the bias voltage when the starting voltage is selected; and a deposition start step of starting to deposit the thin film when the voltage slope is selected.

Meanwhile, a voltage variable-type thin film deposition device including a voltage supply unit for outputting bias voltage, leading thin film material to a targeted object, such that the thin film material is deposited on the targeted object; and a control unit for controlling the voltage supply unit such that the magnitude of the bias voltage being output is continuously varied for a period of time set by a user.

Here, the control unit increases or decreases the magnitude of the bias voltage at least once.

Further, the control unit increases and then decreases the magnitude of the bias voltage, or decreases and then increases the magnitude of the bias voltage at least once.

Further, the power supply unit is a power supply unit included in any one of a Physical Vapor Deposition (PVD)-type thin film deposition device, a Chemical Vapor Deposition (CVD)-type thin film deposition device, and a PVD/CVD mixture-type thin film deposition device.

Further, the bias voltage is any one of Direct Current (DC) bias voltage and pulse-type bias voltage, and the thin film material led and deposited by the bias voltage is one or more types of material.

Here, the control unit can cause variation in the bias voltage to range from 0.5 V or higher to 10 V or lower per minute.

Further, the control unit can vary the bias voltage such that difference between a maximum value and a minimum value of the bias voltage is 50 V or higher.

Further, the control unit performs control such that a maximum value of the bias voltage ranges from 100 V or higher to 250 V or lower.

Further, the control unit performs control such that a minimum value of the bias voltage ranges from 30 V or higher to 80 V or lower.

Further, the control unit varies the bias voltage by applying voltage from low voltage to high voltage or from high voltage to low voltage.

Further, the control unit can vary the bias voltage based on a type of voltage slope selected by the user.

### ADVANTAGEOUS EFFECTS

According to the above-described thin film deposition method and device according to the present invention, when semiconductors are fabricated or thin films are coated on the surfaces of various types of moldings, such a thin film is deposited while bias voltage is varied, so that there is an advantage in that the characteristics of a deposited thin film can be improved.

Further, starting bias voltage can be selected when a thin film is deposited, so that there is an advantage in that a thin film can be deposited such that a single thin film material can be used to be suitable for various uses.

Furthermore, using the configuration of continuously varying bias voltage, a thin film, the characteristics of which are significantly improved, can be deposited, so that there is an advantage in that the equipment thereof can be simplified.

### DESCRIPTION OF DRAWINGS

FIG. 1 is a view showing an example of a thin film formed according to a thin film deposition device and method according to the prior art;

FIG. 2 is a view showing an example of a voltage variable-type thin film deposition method according to the present invention and the variation in the amount of depositions of thin films that are deposited according to the method;

FIG. 3 is a view showing a first example of the voltage variable-type thin film deposition method according to the present invention and a thin film deposited according to the method;

FIG. 4 is a view showing a second example of the voltage variable-type thin film deposition method according to the present invention and a thin film deposited according to the method;

FIG. 5 is a view showing a third example of the voltage variable-type thin film deposition method according to the present invention and a thin film deposited according to the method;

FIG. 6 is a block diagram showing the voltage variable-type thin film deposition method according to the present invention;

FIG. 7 is a schematic diagram showing a voltage variable-type thin film deposition device according to the present invention; and

FIG. 8 is a diagram showing an example to which the voltage variable-type thin film deposition device according to the present invention is applied.

### BEST MODE

A voltage variable-type thin film deposition device and method according to preferred embodiments of the present invention will be described in detail with reference to the attached drawings below.

Although bias voltage, which will be described later, includes both direct current (DC) bias voltage and unipolar pulse-type bias voltage, an example in which the DC bias voltage is varied will be described below.

That is, deposition characteristics can be improved by varying the magnitude of voltage in the case of DC bias voltage or by varying the magnitude of voltage having a predetermined duty ratio in the case of unipolar pulse-type bias voltage. However, since the magnitude of DC voltage and the magnitude of voltage having a predetermined duty ratio are prepared so as to perform substantially the same or a similar action, an example in which the magnitude of DC bias voltage is varied will be described below.

In particular, in the case of unipolar pulse-type bias voltage, bias voltage is applied while alternating between turned-on/off states at predetermined cycles, so that it seems that the unipolar pulse-type bias voltage should be applied for a longer time than the DC bias voltage purely from the viewpoint of the amount of energy.

However, pulses are generated while rapidly repeating turned-on states several hundreds to several thousands times (10 KHz to 100 KHz) per second, so that the turned-off states between the turned-on states hardly affect the speed of deposition of the thin film material in motion and do not increase the time for which bias voltage must be applied.

For example, in the case of unipolar pulse-type bias having a duty ratio of 50:50, voltage does not need to be applied for a period of time twice as long as that of the DC bias voltage in order to deposit a thin film, and it is sufficient to apply the voltage for the same amount of time as the DC bias.

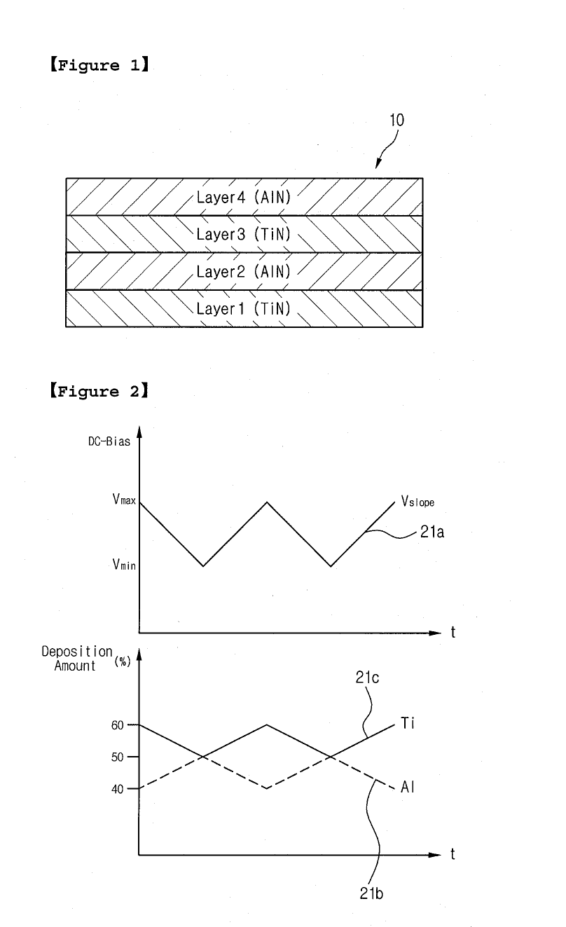

FIG. 2 is a view showing an example of a voltage variable-type thin film deposition method according to the present invention and the variation in the amount of thin film that is deposited according to the method.

As shown in FIG. 2, the voltage variable-type thin film deposition method according to the present invention continuously varies bias voltage, which leads various types of evaporated, sputtered, and ionized thin film material (also referred to as “targets” or “evaporation sources”) to targeted objects, such as a substrate and various types of moldings, such that the thin film material is deposited on the targeted objects, for a period of time or for a part of a period of time during which a thin film is being deposited.

For example, when various types of moldings are coated with a thin film using ionized thin film material in which the at % ratio of titanium ‘Ti’ to aluminum ‘Al’ is 5:5, and using an arc source to which nitrogen ‘N’ is applied as reaction gas, bias voltage is continuously varied for a set time, so that deposition amounts 21b and 21c, in which the ionized titanium and aluminum existing in a vacuum chamber are deposited on the moldings, vary.

That is, it is expected that titanium ions and aluminum ions existing in the vacuum chamber at an at % ratio of 5:5 will be deposited on a molding at a ratio of 5:5. However, as indicated by a voltage slope (Vₛₗₒₚₑ) 21a, when bias voltage is raised and high voltage is applied, aluminum particles, the size of which is relatively small, collide with the molding at a higher speed than titanium particles, and are then deposited on the molding. Thereafter, aluminum particles and titanium particles continuously collide with and are deposited on the molding. Here, a larger number of deposited aluminum particles, compared to that of titanium particles, are emitted (hereinafter referred to as “resputtering”), so that the ratio of the deposition amount 21b of aluminum to the deposition amount 21c of titanium becomes 4:6, even though the ratio differs a little depending on the magnitude of bias voltage.

In contrast, when the bias voltage is lowered and low voltage is applied, the speed of collision of each of the particles is reduced, so that the resputtering of the deposited aluminum particles is reduced, and thus the deposition amount 21b of aluminum increases from approximately 40% to 50% and the deposition amount 21c of titanium decreases from 60% to 50%, thereby reaching a ratio of 5:5.

Therefore, if bias voltage is continuously varied from high voltage to low voltage or from low voltage to high voltage for a predetermined period of time, the above-described variation is continuously generated, so that a mixed thin film that has the advantages of both aluminum and titanium can be coated. Further, bias voltage is slowly and continuously varied, so that separation layers are not generated between thin films, that is, separated portions are not generated between layers, thereby further improving the characteristics of the thin film.

Here, it is preferable that the variation in bias voltage range from 0.5 V or higher to 10 V or lower per minute (V/min), such that the deposition amount of the thin film material varies slowly. This is because, based on the examination results, when the variation in a bias voltage value, that is, the variation from high voltage to low voltage or from low voltage to high voltage, is higher than 10 V, the intrinsic stress of the thin film increases, so that it is difficult to coat the thin film having a thickness of 6 μm or larger, and the state of the thin film becomes unstable, that is, the characteristics of the thin film differ depending on cutting conditions. When the variation in a bias voltage value is lower than 0.5 V, it is difficult to improve the characteristics of the thin film having a thickness of about 3 μm. This is because the characteristics, such as heat resistance, impact resistance, and abrasion resistance, of the thin film can be improved when the thin film has a thickness of at least 6 μm.

Further, when bias voltage is varied from high voltage to low voltage or varied from low voltage to high voltage, it is preferable that the difference between the maximum value Vmax and minimum value Vmin of bias voltage be 50 V or higher. This is because when the difference between the maximum value and the minimum value is not 50 V or higher, a thin film can be deposited to have a thickness of 10 μm or larger, but only abrasion resistance is improved in proportion to the thickness thereof, and other characteristics cannot be improved.

Further, it is preferable that the maximum value of bias voltage range from 100 V or higher to 250 V or lower. This is because when the maximum value is higher than 250 V, a delamination phenomenon occurs and a serious field enhancement phenomenon occurs at respective edge portions of the molding, so that the entire characteristics of the thin film deteriorate. In contrast, when the maximum value is lower than 100 V, toughness is decreased. Although the bias voltage is varied from a maximum value of 100 V (that is, the maximum value decreases to a lower voltage), the characteristics of the thin film can not be improved.

Further, it is preferable that the minimum value of bias voltage range from 30 V to 80 V. This is because, when the minimum value is higher than 80 V, toughness is decreased. In contrast, when the minimum value is lower than 30 V, abrasion resistance is decreased.

Furthermore, based on the intended use of a thin film, bias voltage can be continuously varied by applying voltage from low voltage to high voltage for a predetermined period of time, or can be continuously varied by applying voltage from high voltage to low voltage for a predetermined period of time. Here, as described above, it is preferable that the variation in bias voltage range from 0.5 V or higher to 10 V or lower per minute (V/min), that the difference between the maximum value Vmax and minimum value Vmin of bias voltage be 50 V or higher, that the maximum value range from 100 V or higher to 250 V or lower, and that the minimum value range from 30 V or higher to 80 V or lower.

This is because, when high voltage bias is applied, the thin film preferentially grows on {111} surface having a high density structure, so that the hardness and abrasion resistance thereof can be increased. In contrast, when low voltage bias is applied, a thin film preferentially grows on {200} surface having a low density structure, so that the toughness of a thin film can be increased.

Therefore, it is preferable that bias voltage start from high voltage for products, such as an insert, which requires high abrasion resistance, and it is preferable that bias voltage start from low voltage for products, such as an end mill, which requires high toughness and impact resistance.

In addition, if bias voltage is continuously varied from low voltage to high voltage, or is continuously varied from high voltage to low voltage, crystal grains are restrained from growing on only one of {111} surface or {200} surface, with the result that the atomization of a thin film is achieved, thereby obtaining excellent characteristics for the hardness, abrasion resistance, and toughness of the thin film.

Examples showing the above-described features will be described below. In the case in which a thin film is being deposited for 120 minutes and voltage is selected to vary from high voltage to low voltage, a high voltage of 100 V is selected as a maximum value ranging from 100 V or higher to 250 V or lower, and a low voltage of 50 V is selected as a minimum value ranging from 30 V or higher to 80 V, the difference between the maximum value and the minimum value is 50 V, and the bias voltage decreases by 2.5 V per minute, so that the increase and decrease of bias voltage can be repeated for three cycles.

That is, if the bias voltage starts to decrease from the high voltage of 100 V, that is, the maximum value, by 2.5 V per minute, the bias voltage reaches the low voltage of 50 V, that is, the minimum value, after 20 minutes. Thereafter, if the bias voltage starts to increase from the low voltage of 50 V, that is, the minimum value, by 2.5 V per minute, the bias voltage reaches the high voltage of 100 V, that is, the maximum value, after 20 minutes. Such a cycle is performed three times (40 minutes×3T) for 120 minutes.

Various types of bias voltage, continuously varied for a predetermined period of time as described above, will be described below.

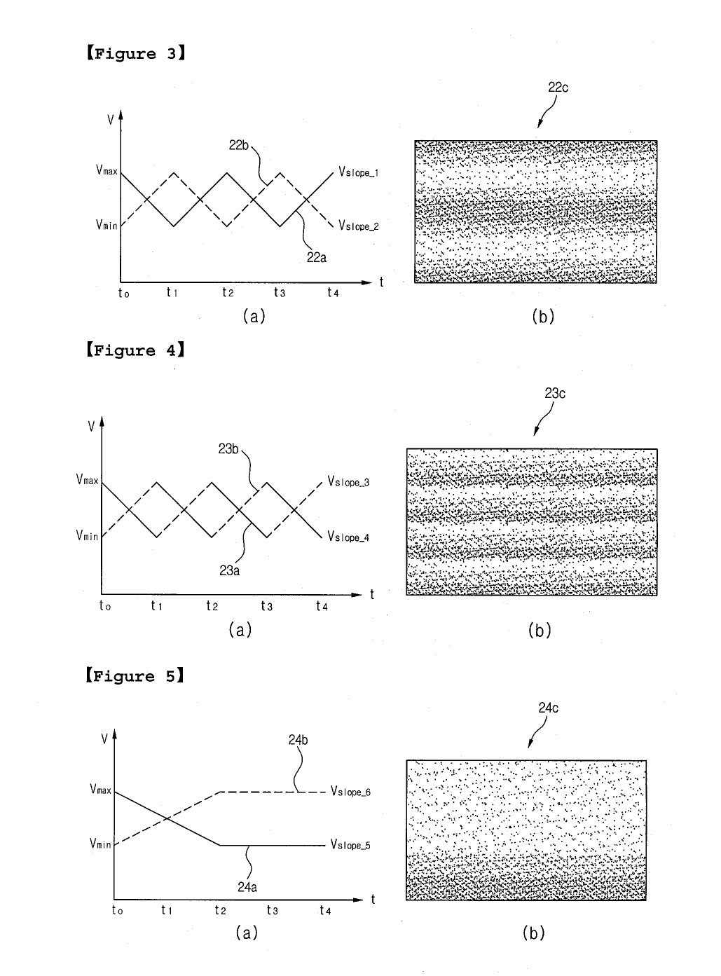

FIG. 3 is a view showing a first example of the voltage variable-type thin film deposition method according to the present invention and a thin film deposited according to the method, FIG. 4 is a view showing a second example of the voltage variable-type thin film deposition method according to the present invention and a thin film deposited according to the method, and FIG. 5 is a view showing a third example of the voltage variable-type thin film deposition method according to the present invention and a thin film deposited according to the method.

First, as shown in (a) of FIG. 3, as indicated by first voltage slope (Vₛₗₒₚₑ_{_{—}}₁) 22a and a second voltage slope (Vₛₗₒₚₑ_{_{—}}₂) 22b, the voltage variable-type thin film deposition method according to the present invention repeatedly and continuously increases or decreases bias voltage (high voltage→low voltage→high voltage→low voltage) for a period of time or for a part of a period of time during which a thin film is being deposited.

Therefore, as shown in (b) of FIG. 3, a deposited thin film 22c is formed in a diffusion structure without forming a separation layer structure, so that it is possible to prevent the interlayer separation of the thin film 22c from other layers and, at the same time, to realize various characteristics, such as toughness, abrasion resistance, and impact resistance.

Here, the fact that it is preferable that the variation in bias voltage range from 0.5 V or higher to 10 V or lower per minute (V/min), that the difference between the maximum value and minimum value of bias voltage be 50 V or higher, that the maximum value range from 100 V or higher to 250 V or lower, and that the minimum value range from 30 V or higher to 80 V or lower has been already described above.

Moreover, when continuously varying bias voltage for a predetermined period of time while improving the hardness and abrasion resistance of a thin film, it is preferable that the bias voltage be varied from high voltage to low voltage, as indicated by the first voltage slope 22a. When increasing the toughness of the thin film 22c while improving the adhesiveness between the molding and thin film 22c, it is preferable that the bias voltage be varied from low voltage to high voltage, as indicated by the second voltage slope 22b.

Further, as shown in (a) of FIG. 4, as indicated by a third voltage slope (Vₛₗₒₚₑ_{_{—}}₃) 23a and a fourth voltage slope (Vₛₗₒₚₑ_{_{—}}₄) 23b, the voltage variable-type thin film deposition method according to the present invention repeatedly and continuously decreases bias voltage (high voltage→low voltage and high voltage→low voltage) or repeatedly and continuously increases bias voltage (low voltage→high voltage and low voltage→high voltage) for a period of time or for a part of a period of time during which a thin film is being deposited.

Therefore, as shown in (b) of FIG. 4, the deposited thin film is formed in a diffusion structure in each layer, so that it is possible to simultaneously realize various characteristics, such as toughness, abrasion resistance, and impact resistance. However, there may be a disadvantage in that the characteristics of the interlayer separation of the thin film 23c are deteriorated compared to those of FIG. 3.

Here, it is preferable that the variation in bias voltage range from 0.5 V or higher to 10 V or lower per minute, that the difference between the maximum value and minimum value of bias voltage be 50 V or higher, that the maximum value range from 100 V or higher to 250 V or lower, and that the minimum value range from 30 V or higher to 80 V or lower. Further, based on the intended usage of the thin film 23c, it is preferable that the bias voltage be varied from high voltage to low voltage, as indicated by the third voltage slope 23a, or be varied from low voltage to high voltage, as indicated by the fourth voltage slope 23b.

Further, as shown in (a) of FIG. 5, as indicated by a fifth voltage slope (Vₛₗₒₚₑ_{_{—}}₅) 24a and a sixth voltage slope (Vₛₗₒₚₑ_{_{—}}₆) 24b, the voltage variable-type thin film deposition method according to the present invention continuously and repeatedly decreases or maintains the bias voltage (high voltage→low voltage→low voltage) or increases or maintains the bias voltage (low voltage→high voltage→high voltage) for a period of time or for a part of a period of time during which a thin film is being deposited.

Therefore, as shown in (b) of FIG. 5, the deposited thin film is formed in a diffusion structure without forming a separation layer structure, so that it is possible to prevent the interlayer separation of the thin film 24c from other layers, and to simultaneously realize various characteristics, such as toughness, abrasion resistance, and impact resistance. In particular, according to the fifth voltage slope 24a and the sixth voltage slope 24b, the suitability of a thin film for its intended use can be improved by increasing or decreasing the bias voltage more slowly.

Here, it is preferable that the variation in bias voltage range from 0.5 V or higher to 10 V or lower per minute, that the difference between the maximum value and minimum value of bias voltage be 50 V or higher, that the maximum value range from 100 V or higher to 250 V or lower, and that the minimum value range from 30 V or higher to 80 V or lower. Further, based on the intended use of the thin film 24c, it is preferable that the bias voltage be varied from high voltage to low voltage, as indicated by the fifth voltage slope 24a, or that it be varied from low voltage to high voltage, as indicated by the sixth voltage slope 24b.

Thin film deposition processes according to the voltage variable-type thin film deposition method according to the present invention will be described below.

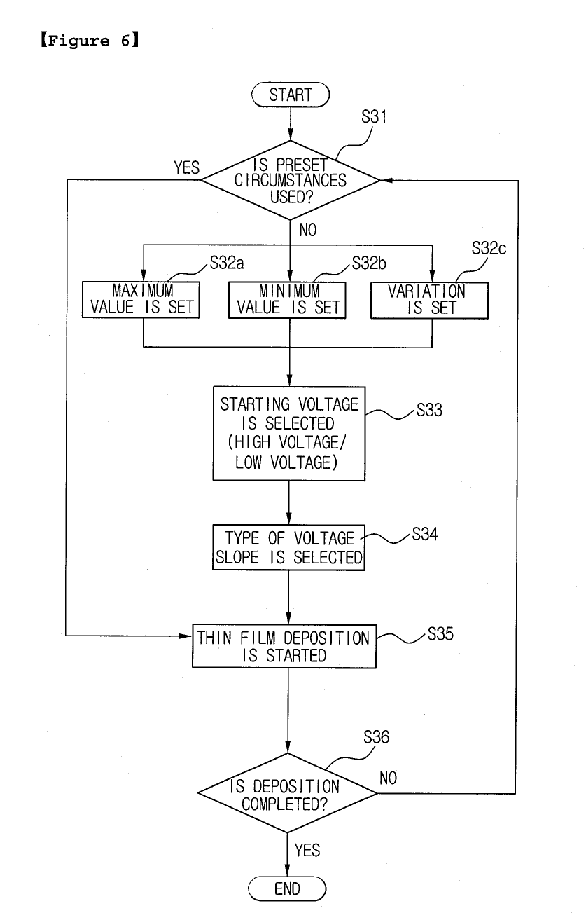

FIG. 6 is a block diagram showing the voltage variable-type thin film deposition method according to the present invention.

As shown in FIG. 6, in order to perform thin film deposition according to the present invention, first, it is determined whether to use preset circumstances, such as the maximum value, minimum value, and variation in bias voltage, so as to perform corresponding thin film deposition at step S31. If a user selects to use the preset circumstances, the thin film deposition is started based on the preset circumstances at step S35.

Meanwhile, in the case in which thin film deposition is performed by setting new circumstances, the respective circumstances, such as the maximum value, minimum value, and variation in bias voltage, are set through key input by a user at steps S32a, S32b, and S32c.

After the circumstances are set at steps S32a, S32b, and S32c, starting bias voltage is selected based on the intended use of a thin film at step S33. That is, whether to vary the bias voltage from low voltage to high voltage, or vary the bias voltage from high voltage to low voltage is selected at step S33.

After the starting bias voltage is selected at step S33, the type of voltage slope is selected at step S34. For example, any one type of voltage slope is selected from among various types of voltage slopes 22a, 22b, 23a, 23b, 24a, and 25b, described in conjunction with FIGS. 3 to 5. However, it is apparent to those skilled in the art that it is possible to set and select various types of voltage slopes, in which bias voltage is continuously varied, as well as the above-described voltage slopes.

When the type of voltage slope is selected at step S34, the thin film deposition is started at step S35, and then whether the deposition is completed is determined. If the deposition is completed, the process is terminated. If the deposition is not completed, the above-described routines are repeated.

As described above, since the application of bias voltage is set through the selection of a user, it is possible to prevent the interlayer separation of a thin film from other layers, to realize various characteristics, such as toughness, abrasion resistance, and impact resistance, simultaneously, and to fabricate a thin film which is suitable for the intended use thereof.

A voltage variable-type thin film deposition device according to the present invention will be described in detail with reference to the accompanying drawings below.

FIG. 7 is a schematic diagram showing the voltage variable-type thin film deposition device according to the present invention.

First, as shown in FIG. 7, the voltage variable-type thin film deposition device according to the present invention includes a user key input unit 45 for receiving user instructions so as to set the above-described circumstances of bias voltage and to start thin film deposition, memory 42 for storing information data, such as the set bias voltage, and a display unit 44 for displaying set circumstance values, predetermined set circumstance values, and the progress state of the thin film deposition, which are input through the key input unit 45, a power supply unit 41 for applying bias voltage to a Physical Vapor Deposition (PVD)-type thin film deposition device, a Chemical Vapor Deposition (CVD)-type thin film deposition device, or a PVD/CVD mixture-type thin film deposition device based on the set circumstance value, and a control unit 43 for processing data so as to write the circumstance set values, input through the key input unit 45, in the memory 42 or to read them from the memory 42, and for controlling the output of the power supply unit 41 based on the set circumstance values.

Therefore, it is possible to deposit a thin film while continuously varying bias voltage for a predetermined period of time, through the setting of a user.

Examples to which the above-described voltage variable-type thin film deposition device according to the present invention is applied will be described below. Of the various-type thin film deposition devices, such as the PVD, CVD, and PVD/CVD mixture-type thin film deposition devices, an ion plating device using arc sources will be described as an example below.

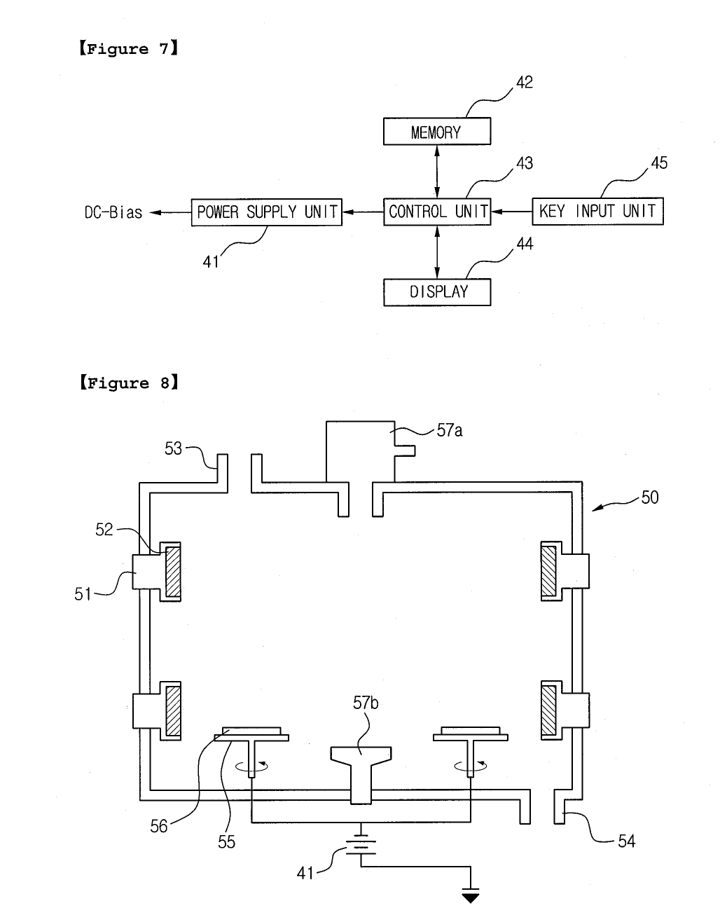

FIG. 8 is a diagram showing an example to which the voltage variable-type thin film deposition device according to the present invention is applied.

As shown in FIG. 8, the ion plating device using arc sources includes a vacuum chamber 50, which has a reaction gas inlet 53 through which reaction gas can flow in, and a reaction gas outlet 54 the inside of which can be in a vacuum state and through which reaction gas can flow out, one or more arc generation sources 51, which are provided on one side of the vacuum chamber 50 and melt or evaporate a cathode 52, that is, an arc evaporation source (or thin film material), using arc discharge, and a substrate holder 55, which supports a substrate (or a molding) 56 to be ion-plated and receives bias voltage so as to pull evaporated minute particles ionized by acceleration electrons.

Further, if necessary, the ion plating device using arc sources further includes an auxiliary anode (not shown) provided between the arc evaporation source 51 and the substrate 56, as well as a Hollow Cathode Discharge (HCD) gun 57a and a hearth 57b, to which negative potential (−) and positive potential (+) are respectively applied so as to increase the adhesiveness and uniformity of a thin film by washing the surface of the substrate 56 using ions before the thin film is deposited on the substrate 56 using the above-described arc discharge.

Meanwhile, in the above-described ion plating device, titanium ‘Ti’ and aluminum ‘Al’ are used as arc evaporation sources, initial vacuum pressure in the vacuum chamber 50 is set to 5×10⁻⁵ Torr, heating to 500° C. is performed using a heater inside the vacuum chamber 50, and washing is performed using ion-enhanced glow discharge so as to improve the adhesiveness between the substrate 56 and the thin film.

Thereafter, the thin film deposition is started while arc current is maintained at 100 A and the degree of vacuum is maintained at 25 mTorr by causing nitrogen ‘N’ gas to flow in.

Here, the voltage supply unit 41 applies bias voltage to the substrate holder 55 for supporting the substrate 56 that is to be ion-plated so as to pull minute titanium particles and aluminum particles existing in the vacuum chamber 50 at an at % ratio of 5:5. This bias voltage is continuously varied for a predetermined period of time selected by a user. It is preferable that the variation in the bias voltage range from 0.5 V or higher to 10 V or lower per minute (V/min), that the difference between the maximum value and minimum value of bias voltage be 50 V or higher, that the maximum value range from 100 V or higher to 250 V or lower, that the minimum value range from 30 V or higher to 80 V or lower, and that the bias voltage be selected to be varied from high voltage to low voltage or varied from low voltage to high voltage.

That is, as the above-described example, in the case of a process of depositing a thin film for 120 minutes, first, the bias voltage is selected to be varied from high voltage to low voltage, a high voltage of 100 V is selected as a maximum value, a low voltage of 50 V is selected as a minimum value, and the bias voltage is continuously varied by 2.5 V per minute, so that the increase/decrease of the bias voltage, as shown in FIG. 3, can be repeated for three cycles.

Therefore, as described above, the deposited thin film is formed in a diffusion structure without forming a separation layer structure, so that it is possible to prevent the interlayer separation of the thin film from other layers and to simultaneously realize various characteristics, such as toughness, abrasion resistance, and impact resistance. Furthermore, since starting bias voltage can be selected, a thin film can be deposited to be suitable for the intended use thereof.

The voltage variable-type thin film deposition method and device has been described above. It will be understood by those skilled in the art that the technical configuration of the present invention can be made in the form of other preferred embodiments without departing from the technical spirit and essential features of the present invention.

In particular, although the embodiments in which thin films are deposited to coat various moldings have been described as examples in detail, the present invention is not limited thereto. Further, it will be apparent to those skilled in the art that the above-described present invention can be applied to the fabrication of semiconductors, such as a gate, a bit line, an insulating layer (or a spacer), and a via, which require a process of depositing a thin film.

Further, although only DC bias voltage and unipolar pulse-type bias voltage have been used as examples of bias voltage, it will be apparent to those skilled in the art that a thin film can be deposited while Alternating Current (AC)-type power, including a high frequency (Radio Frequency (RF)), is continuously increased or decreased for a predetermined time, with the exception of numerical restrictions, such as the above-described variable voltage value per minute, maximum value, minimum value, and the difference between the maximum value and the minimum value.

Therefore, it should be understood that the above-described embodiments are illustrative in all aspects rather than limiting, that the scope of the present invention will be disclosed in the accompanying claims, which are set forth below, rather than the above-described embodiments, and that the meanings and ranges of claims and all modifications derived from equivalent conceptions thereof fall within the scope of the present invention.

### INDUSTRIAL APPLICABILITY

The present invention relates, in general, to a voltage variable-type thin film deposition method and device used to fabricate semiconductors or to coat the surfaces of various types of moldings, and, more particularly, to a voltage variable-type thin film deposition method and device, in which bias voltage is continuously varied, and a thin film is deposited at selected starting bias voltage based on the intended use of the thin film, thereby improving thin film characteristics and deposition characteristics, and simplifying equipment.

1. A voltage variable-type thin film deposition method, comprising: applying bias voltage, leading thin film material to a targeted object such that the thin film material is deposited on the targeted object, while continuously varying a magnitude of the bias voltage for a period of time set by a user.

2. The voltage variable-type thin film deposition method according to claim 1, wherein the magnitude of the bias voltage increases or decreases at least once for the period of time set by the user.

3. The voltage variable-type thin film deposition method according to claim 2, wherein the magnitude of the bias voltage increases and then decrease or decreases and then increases at least once for the period of time set by the user.

4. The voltage variable-type thin film deposition method according to claim 1, wherein the bias voltage is applied to any one of a Physical Vapor Deposition (PVD)-type thin film deposition device, a Chemical Vapor Deposition (CVD)-type thin film deposition device, and a PVD/CVD mixture-type thin film deposition device.

5. The voltage variable-type thin film deposition method according to claim 1, wherein the bias voltage is any one of Direct Current (DC) bias voltage and pulse-type bias voltage, and the thin film material led and deposited by the bias voltage is one or more types of material.

6. The voltage variable-type thin film deposition method according to claim 1, wherein variation in the bias voltage ranges from 0.5 V or higher to 10 V or lower per minute.

7. The voltage variable-type thin film deposition method according to claim 1, wherein the bias voltage is varied such that difference between a maximum value and a minimum value of bias voltage is 50 V or higher.

8. The voltage variable-type thin film deposition method according to claim 1, wherein a maximum value of the bias voltage ranges from 100 V or higher to 250 V or lower.

9. The voltage variable-type thin film deposition method according to claim 1, wherein a minimum value of the bias voltage ranges from 30 V or higher to 80 V or lower.

10. The voltage variable-type thin film deposition method according to claim 1, wherein the bias voltage is varied by applying voltage from low voltage to high voltage or from high voltage to low voltage.

11. The voltage variable-type thin film deposition method according to claim 1, comprising: a determination step of determining whether to use preset bias voltage values; a step of depositing a thin film based on the preset bias voltage values if, as a result of the determination, it is determined to use the preset bias voltage values, and setting new bias voltage values if it is determined to use new bias voltage values; a starting voltage selection step of selecting whether to apply voltage from low bias voltage or from high bias voltage when new bias voltage values are set; a voltage slope selection step of selecting an increasing/decreasing slop type for the bias voltage when the starting voltage is selected; and a deposition start step of starting to deposit the thin film when the voltage slope is selected.

12. A voltage variable-type thin film deposition device comprising: a voltage supply unit for outputting bias voltage, leading thin film material to a targeted object, such that the thin film material is deposited on the targeted object; and a control unit for controlling the voltage supply unit such that a magnitude of the bias voltage being output is continuously varied for a period of time set by a user.

13. The voltage variable-type thin film deposition device according to claim 12, wherein the control unit increases or decreases the magnitude of the bias voltage at least once.

14. The voltage variable-type thin film deposition device according to claim 13, wherein the control unit increases and then decreases the magnitude of the bias voltage, or decreases and then increases the magnitude of the bias voltage at least once.

15. The voltage variable-type thin film deposition device according to claim 12, wherein the power supply unit is a power supply unit included in any one of a Physical Vapor Deposition (PVD)-type thin film deposition device, a Chemical Vapor Deposition (CVD)-type thin film deposition device, and a PVD/CVD mixture-type thin film deposition device.

16. The voltage variable-type thin film deposition device according to claim 12, wherein the bias voltage is any one of Direct Current (DC) bias voltage and pulse-type bias voltage, and the thin film material led and deposited by the bias voltage is one or more types of material.

17. The voltage variable-type thin film deposition device according to claim 12, wherein the control unit can cause variation in the bias voltage to range from 0.5 V or higher to 10 V or lower per minute.

18. The voltage variable-type thin film deposition device according to claim 12, wherein the control unit can vary the bias voltage such that difference between a maximum value and a minimum value of the bias voltage is 50 V or higher.

19. The voltage variable-type thin film deposition device according to claim 12, wherein the control unit performs control such that a maximum value of the bias voltage ranges from 100 V or higher to 250 V or lower.

20. The voltage variable-type thin film deposition device according to claim 12, wherein the control unit performs control such that a minimum value of the bias voltage ranges from 30 V or higher to 80 V or lower.

21. The voltage variable-type thin film deposition device according to claim 12, wherein the control unit varies the bias voltage by applying voltage from low voltage to high voltage or from high voltage to low voltage.

22. The voltage variable-type thin film deposition device according to claim 12, wherein the control unit can vary the bias voltage based on a type of voltage slope selected by the user.
